(19) United States
(12) Patent Application Publication
(10) Pub. No.: US 2024/0369630 A1
(43) Pub. Date: Nov. 7, 2024

(54) GLITCH FILTER

(71) Applicant: Nordic Semiconductor ASA, Trondheim (NO)

(72) Inventors: Christian HERGOT, Trondheim (NO); John Raul REBOLLOS, Trondheim (NO); Arne VENÅS, Trondheim (NO); Kaspar MOULIN, Trondheim (NO)

(73) Assignee: Nordic Semiconductor ASA, Trondheim (NO)

(21) Appl. No.: 18/648,172

(22) Filed: Apr. 26, 2024

(30) Foreign Application Priority Data
May 3, 2023 (GB) 2306557.6

(51) Int. Cl. G01R 31/3185; H03H 17/02; H03K 5/00; H03K 5/01; H03K 19/20

(52) U.S. Cl. CPC G01R 31/318594; H03H 17/02; H03K 2005/00013; H03K 5/01; H03K 19/20

(57) ABSTRACT

A circuit portion for filtering digital signals comprises a first delay circuit portion, a second delay circuit portion, and a logic circuit portion. The first delay circuit portion introduces a time delay to rising edges of an input signal and outputs a first delayed digital signal. The second delay circuit portion introduces a time delay to falling edges of the input signal and outputs a second delayed digital signal. The logic circuit portion outputs a signal which retains a current state when the first and second delayed signals have different states, and a state that is dependent on a state of the first and second delayed signals when the first and second delayed 10 signals have the same state. The circuit portion effectively removes glitches—i.e. pulses of short duration—from the input signal.

### CROSS REFERENCE TO RELATED APPLICATION

This application claims priority from Great Britain Application No. 2306557.6, filed May 3, 2023, which application is incorporated herein by reference in its entirety.

### FIELD

The present invention relates to digital signal processing, and more particularly to circuitry for filtering or removal of glitches in digital signals.

### BACKGROUND

Glitches, in the context of digital signals, typically take the form of short positive or negative pulses in a digital signal which are unintended—i.e. they do not form part of the informational content of the signal. Glitches can arise in electronic devices for a number of reasons, e.g. pad inputs (button ripples), short circuits on input pins, interference from nearby electronic devices, etc.

It is desirable to avoid glitches in digital signals, as these can cause digital signal processing to fail e.g. where a glitch is incorrectly interpreted by digital logic to form part of an input signal. So-called glitch filters have been used in prior electronic devices in order to remove these glitches from digital signals before they cause failure in processing of those signals.

Some prior glitch filters remove glitches from a digital signal by using a string of digital delay cells which introduce a time delay the digital signal. Several nodes from the string of delay cells are logically combined e.g. using AND gates, and clocked out using a flip-flop, in order to effectively change the duration of ‘short’ pulses from the digital signal such that overly short duration pulses are removed. However, such prior glitch filters suffer from meta-stability issues, and can unintentionally influence the informational content of the digital signal as transmitted by altering the time periods between rising and falling edges in that signal. Furthermore, such solutions are typically not readily adjustable, and require the maximum glitch duration which is removed by the filter to be set, by design, on manufacture.

The present invention aims to address at least some of the issues set out above.

### SUMMARY OF THE INVENTION

When viewed from a first aspect, the present invention provides a circuit portion for filtering digital signals, the circuit portion comprising:
an overall signal input for receiving a digital input signal, and an overall signal output for outputting a digital output signal;
a first delay circuit portion coupled to the signal input and configured to output a first delayed digital signal comprising one or more leading edges each corresponding to a rising edge of the input signal, and one or more trailing edges each corresponding to a falling edge of the input signal, each of said leading edges in the first delayed digital signal being subject to a first time delay relative to the corresponding rising edge in the input signal such that a time period between each leading edge and the ensuing trailing edge is shorter than a time period between the corresponding rising edge and ensuing falling edge in the input signal, the first delay circuit portion being configured such that it does not output a corresponding leading and trailing edge in the first delayed signal when the time period between the rising edge and the ensuing falling edge in the input signal is less than or equal to the first time delay;
a second delay circuit portion coupled to the signal input and configured to output a second delayed digital signal comprising one or more leading edges each corresponding to a falling edge of the input signal, and one or more trailing edges each corresponding to a rising edge of the input signal, each of said leading edges in the second delayed digital signal being subject to a second time delay relative to the corresponding falling edge in the input signal such that a time period between each leading edge and the ensuing trailing edge is shorter than a time period between the corresponding falling edge and ensuing rising edge in the input signal, the second delay circuit portion being configured such that it does not output a corresponding leading and trailing edge in the second delayed signal when the time period between the falling edge and the ensuing rising edge in the input signal is less than or equal to the second time delay; and
a logic circuit portion comprising a first input coupled to the first delay circuit portion, and a second input coupled to the output of the second delay circuit portion, the logic circuit portion being configured to output, to the overall signal output, the digital output signal which retains a current state when the first and second delayed digital signals have different states, and a state that is dependent on a state of the first and second delayed signals when the first and second delayed digital signals have the same state.

Thus it will be seen that the first delay circuit portion may effectively remove positive pulses (i.e. pulses between a rising edge and an ensuing falling edge) in the input signal which have a duration less than or equal to the first time delay introduced to the rising edges by it. Similarly, the second delay circuit portion effectively removes negative pulses (i.e. pulses between a falling edge and an ensuing rising edge) in the input signal which have a duration less than or equal to the second time delay introduced to the falling edges by it. When pulses have durations longer than these thresholds, the first and second delay circuit portions may effectively reduce the durations of positive and negative pulses in the input signal respectively.

The logic circuit portion then combines the outputs of the two delay circuit portions in such a manner that the signal it outputs, while delayed relative to the input signal, has both positive and negative pulses of short duration removed therefrom. Advantageously, the durations of pulses of longer duration in the input signal which are not removed by the circuit portion are kept the same as those in the input signal, thereby maintaining the information content of the input signal without requiring adjustments to subsequent logic circuitry in order to account for this.

Furthermore, it will be appreciated that the threshold durations for which positive and negative pulses are removed from the output signal are easily adjustable by simply altering the first and second time delays introduced by the first and second delay circuit portions respectively to rising and falling edges in the input signal. The circuit portion in accordance with the present invention therefore provides a more robust glitch filter than prior solutions, and one which is readily configurable.

The terms leading and trailing edges, as used herein, should be interpreted to be independent of edge direction, as per the standard meaning in the art. Where a leading edge is a rising edge, a trailing edge is a falling edge, and where a leading edge is a falling edge, a trailing edge is a rising edge.

Although not essential, in a set of embodiments, the first and the second time delays are equal to each other. This may advantageously ensure that the duration thresholds at which both positive and negative pulses are filtered out are equal, thus ensuring that both types of pulses are filtered out equally by the circuit portion.

In a set of embodiments, the output signal output by the logic circuit portion has a state which matches the state of the two delayed signals when the two delayed signals have the same state. In a set of embodiments, the logic circuit portion is a Muller-C circuit portion. In other words, the logic circuit portion may operate as a Muller-C element or C-element.

In a set of embodiments, the first delay circuit portion and the second delay circuit portion have substantially the same arrangement, except for the second delay circuit portion comprising an inverter at an input thereof such that the second delay circuit receives an inverted version of the input signal. This may advantageously enable substantially the same circuit design to be used for both delay circuit portions, thus increasing standardisation across different devices and reducing the effects of process, voltage and temperature (PVT) variations between the two delay circuit portions.

In a set of embodiments, the first and/or second delay circuit portion comprises a capacitance element and an impedance element arranged such that:
upon receipt of a first type of edge of the input signal, a first current path is formed between the capacitance element and a first supply rail;
upon receipt of a second type of edge of the input signal, a second current path is formed between the capacitance element and a second supply rail; and
   wherein:
the impedance element forms part of the second current path, and does not form part of the first current path.

Thus it will be seen that this configuration may enable different propagation delays to be introduced to the two different types of edges, since only the second current path includes the impedance element and thus has a larger time constant than the first current path.

The first type of edge may be a falling edge, and the second type of edge may be a rising edge. The first supply rail may be a positive supply rail, and the second supply rail may be a negative supply rail or ground.

In a set of embodiments, the first and/or second delay circuit portion comprises:
a first inverter having an input terminal coupled to the overall signal input terminal;
a second inverter having an input terminal coupled to an output terminal of the first inverter;
a first transistor of a first type having a first terminal coupled to a positive supply rail and a gate terminal coupled to an output terminal of the second inverter;
a first transistor of a second type having a first terminal coupled to a negative supply rail and a gate terminal coupled to the output of the second inverter;
a second transistor of the first type having a first terminal coupled to the positive supply rail and a gate terminal coupled to a second terminal of the first transistor of the first type;
a second transistor of the second type having a first terminal coupled to the negative supply rail and a gate terminal coupled to the output terminal of the first inverter; and
an AND gate having a first input terminal coupled to the output terminal of the second inverter, and a second input terminal coupled to a second terminal of the second transistor of the first type and to a second terminal of the second transistor of the second type, the AND gate providing said first delayed digital signal;
   wherein:
a first terminal of the impedance element is coupled to the second terminal of the first transistor of the first type, to the gate terminal of the second transistor of the first type, and to a first terminal of the capacitance element;
a second terminal of the impedance element is coupled to a second terminal of the first transistor of the second type; and
a second terminal of the capacitance element is connected to the negative supply rail.

In some embodiments, said transistors of the first type may comprise PMOS transistors, and said transistors of the second type may comprise NMOS transistors. The first terminals of said transistors may comprise source terminals, and the second terminals of said transistors may comprise drain terminals. Equally, the transistors of the first and second types may comprise NMOS and PMOS transistors respectively, and/or the first and second terminals may be drain and source terminals respectively.

The impedance element may comprise a resistor. It may comprise a plurality of resistors. The capacitance element may comprise a capacitor. It may comprise a plurality of capacitors. The capacitor may comprise a transistor having its drain and source terminals connected together. This may enable the delay circuit portion to be kept physically small, as capacitors typically require a larger circuit area than transistors.

In a set of embodiments, the logic circuit portion comprises a first mutex circuit portion having first and second inputs and being configured to output a first mutex signal which retains a current state when said first and second inputs are in the same, predetermined state, and which has a state that matches the state of the first input mutex signal in all other cases.

The inclusion of a mutex—i.e. mutual exclusion—circuit portion in the logic circuit portion may advantageously help combat meta-stability in the output of the circuit portion, thereby providing an even more robust glitch filter compared to prior solutions.

In a set of embodiments, the first mutex circuit portion is further configured to output a second mutex signal which retains a current state when said first and second inputs are in the same, predetermined state, and which has a state that matches the state of the second input mutex signal in all other cases. The first state may be a high or logical ‘1’ state. The second mutex signal may be an inverted version of the first mutex signal.

In a set of embodiments, the first or the second output of the first mutex circuit portion is coupled to the overall signal output. Either output terminal of the mutex circuit portion may be suitable for providing the output digital signal, depending on configuration, since they may each be inverted versions of one another.

In a set of embodiments, the first mutex circuit portion comprises:
a first and a second NAND gate each having two input terminals and an output terminal;
a first and a second transistor of a first type, each transistor comprising a gate terminal, a first terminal and a second terminal; and
a first and a second transistor of a second type, each transistor comprising a gate terminal, a first terminal and a second terminal;
   wherein:
a first input terminal of the first NAND gate provides the first input of the first mutex circuit portion, a second input terminal of the first NAND gate is coupled to the output terminal of the second NAND gate, and the output terminal of the first NAND gate is coupled to the first terminal of the first transistor of the first type;
a first input terminal of the second NAND gate is coupled to the output terminal of the first NAND gate, a second input terminal of the second NAND gate is coupled to the second input terminal of the first mutex circuit portion, and the output terminal of the second NAND gate is coupled to the first terminal of the second transistor of the first type;
the second terminal of the first transistor of the first type is coupled to the second terminal of the first transistor of the second type, and to the first output terminal of the first mutex circuit portion;
the first terminal of the first transistor of the second type is coupled to ground;
the second terminal of the second transistor of the first type is coupled to the second terminal of the second transistor of the second type, and to the second output terminal of the first mutex circuit portion;
the first terminal of the second transistor of the second type is coupled to ground; and
the gate terminals of the first transistor of the first type and the first transistor of the second type are coupled to the output terminal of the second NAND gate; and
the gate terminals of the second transistor of the first type and the second transistor of the second type are coupled to the output terminal of the first NAND gate.

In some embodiments, said transistors of the first type may comprise PMOS transistors, and said transistors of the second type may comprise NMOS transistors. The first terminals of each of said transistors may be source terminals, and the second terminals of each of said transistors may be drain terminals. Equally, the transistors of the first and second types may comprise NMOS and PMOS transistors respectively, and/or the first and second terminals may be drain and source terminals respectively.

This configuration of the two NAND gates may cause the mutex circuit portion to provide the logical functionality outlined above, and the configuration of the PMOS and NMOS transistors may operate as a meta-stability filter thus removing any possibility for meta-stability in either mutex output signal.

In a set of embodiments, the logic circuit portion further comprises a single-ended amplifier coupled between the first or second output terminal of the first mutex circuit portion and the output of the logic circuit portion. This may help isolate the mutex circuit portion from any interference experienced at the output of the logic circuit portion.

In a set of embodiments, the logic circuit portion comprises:
a NAND gate having a first input terminal coupled to the output terminal of the first delay circuit portion, a second input terminal connected to the output terminal of the second delay circuit portion, and an output terminal coupled to the first input terminal of the first mutex circuit portion; and
an OR gate having a first input terminal coupled to the output terminal of the first delay circuit portion, a second input terminal coupled to an output of the second delay circuit portion, and an output terminal coupled to the second input terminal of the first mutex circuit portion.

In a set of such embodiments, the circuit portion further comprises an inverter connected between the output of the first delay circuit portion and the first input terminals of the NAND gate and OR gate.

In an alternative set of embodiments, the logic circuit portion comprises:
a first inverter having an input terminal coupled to an output of the first delay circuit portion;
a second inverter having an input terminal coupled to an output of the second delay circuit portion;
a first NAND gate having a first input terminal coupled to an output terminal of the first inverter, a second input terminal coupled to the output of the second delay circuit portion, and an output terminal coupled to the first input of the first mutex circuit portion; and
a second NAND gate having a first input terminal coupled to the output terminal of the first delay circuit portion, a second input terminal coupled to an output terminal of the second inverter, and an output terminal coupled to the second input terminal of the first mutex circuit portion.

In a set of embodiments, the output of the logic circuit portion is inverted to provide the digital output signal.

In an alternative set of embodiments, the logic circuit portion further comprises a second mutex circuit portion having the same arrangement as the first mutex circuit portion, wherein the two mutex circuit portions are cross-coupled.

The inclusion of two mutex circuit portions in the logic circuit portion in this configuration may help further combat meta-stability in the output of the logic circuit portion.

In a set of such embodiments, the logic circuit portion comprises a NOR gate in the cross-coupling to provide a reset input.

In a set of embodiments, the circuit portion further comprises:
a first inverter connected between the output of the first delay circuit portion and the first input of the first mutex circuit portion; and
a second inverter connected between the output of the second delay circuit portion and the first input of the second mutex circuit portion.

### BRIEF DESCRIPTION OF THE DRAWINGS

Embodiments of the invention will now be described, by way of example only, with reference to the accompanying drawings in which:

FIG. 1 is a schematic block diagram illustrating a digital filtering circuit portion in accordance with a first embodiment of the invention;

FIGS. 2a and 2b are timing diagrams indicating how the states of different signals in the described embodiments change in the case of ‘long’ duration pulses in the input signal;

FIGS. 3a and 3b are timing diagrams indicating how the states of different signals in the described embodiments change in the case of ‘short’ duration pulses in the input signal;

FIG. 4 is a schematic diagram illustrating a digital filtering circuit portion in accordance with a second embodiment of the invention;

FIG. 5 is a schematic diagram illustrating a digital filtering circuit portion in accordance with a third embodiment of the invention;

FIG. 6 is a schematic diagram illustrating a digital filtering circuit portion in accordance with a fourth embodiment of the invention;

FIG. 7 is a schematic diagram illustrating a delay circuit portion for use in digital filtering circuit portions in accordance with embodiments of the invention; and

FIG. 8 is a schematic diagram illustrating a mutex circuit portion for use in digital filtering circuit portions in accordance with embodiments of the invention.

### DETAILED DESCRIPTION OF THE DRAWINGS

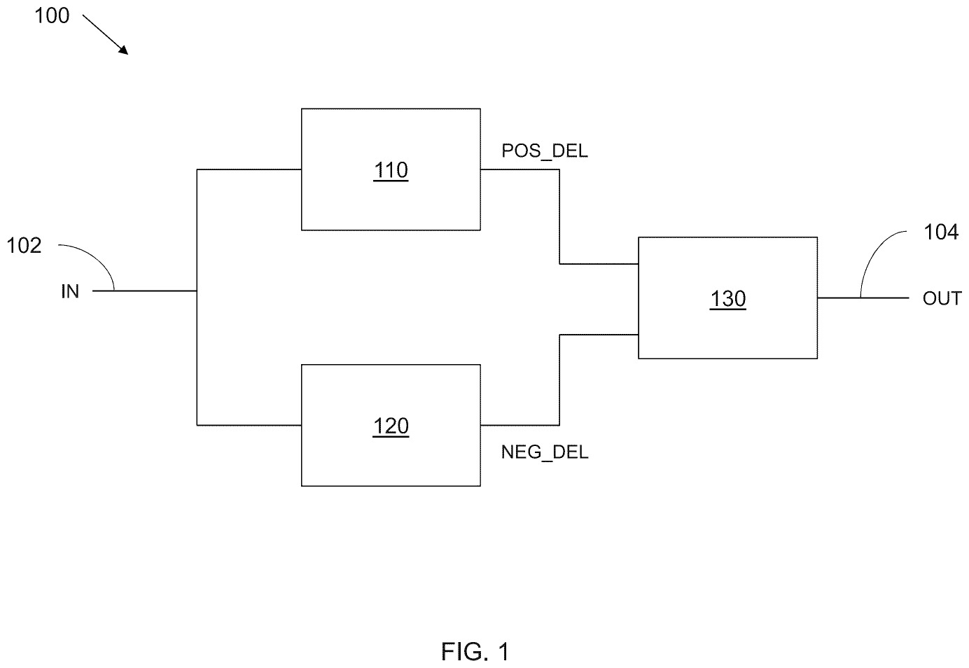

FIG. 1 is a schematic block diagram of a circuit portion 100 for filtering digital signals in accordance with the present invention. The circuit portion 100 comprises an overall signal input 102 for receiving a digital input signal IN, an overall signal output 104 for outputting a filtered digital signal OUT, a first delay circuit portion 110, a second delay circuit portion 120 and a logic circuit portion 130.

The inputs of the first and second delay circuit portions 110, 120 are coupled to the overall signal input 102. The output of the first delay circuit portion 110 is coupled to a first input of the logic circuit portion 130. The output of the second delay circuit portion 120 is coupled to a second input of the logic circuit portion 130. An output of the logic circuit portion 130 is coupled to the overall signal output 104.

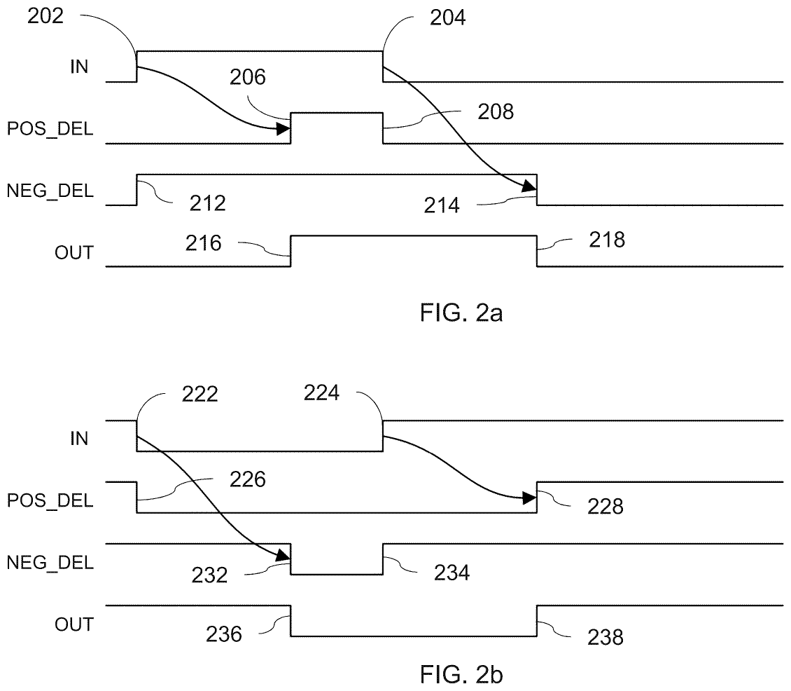

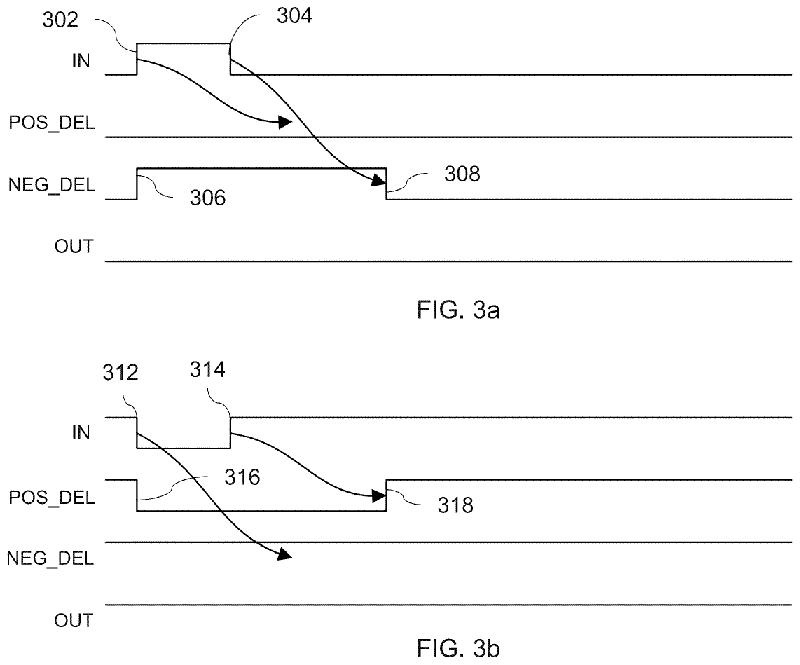

As will be explained below, with reference to FIGS. 2 and 3, the first delay circuit portion 110 receives the digital input signal IN and outputs a first delayed digital signal POS_DEL having leading edges corresponding to rising edges in the input signal IN and trailing edges corresponding to falling edges in the input signal IN. The leading edges in the first delayed signal POS_DEL are subject to a propagation or time delay introduced by the first delay circuit portion 110 relative to the corresponding rising edges in the input signal IN. The leading and trailing edges of the first delayed signal POS_DEL may be rising or falling edges, dependent on configuration.

When the time period between a rising edge and the ensuing falling edge of the input signal IN is greater than the time delay introduced by the first delay circuit portion 110, the first delayed signal POS_DEL includes a corresponding leading and ensuing trailing edge having a reduced time period therebetween. In this embodiment, the time delay between the leading and ensuing trailing edge in the first delayed signal POS_DEL is reduced relative to the time period between the corresponding rising and falling edge in the input signal IN by the time delay introduced by the first delay circuit portion 110.

When the time period between a rising edge and the ensuing falling edge of the input signal IN is less than or equal to the time delay introduced by the first delay circuit portion 110, no corresponding edges are included in the first delayed signal POS_DEL. The first delay circuit portion 110 therefore effectively filters out positive pulses in the input signal IN which a duration less than or equal to the time delay introduced by the first delay circuit portion 110.

The second delay circuit portion 120 also receives the digital input signal IN and outputs a second delayed digital signal NEG_DEL having leading edges corresponding to falling edges in the input signal IN and trailing edges corresponding to rising edges in the input signal IN. The leading and trailing edges may be rising or falling edges dependent on configuration. The second delay circuit portion 120 operates in much the same manner as the first delay circuit portion 110, except it introduces a propagation or time delay to falling edges in the input signal IN, rather than to rising edges.

Thus, when the time period between a falling edge and the ensuing rising edge of the input signal IN is greater than the time delay introduced by the second delay circuit portion 120, the second delayed signal NEG_DEL includes a corresponding leading and ensuing trailing edge having a reduced time period therebetween. In this embodiment, the time delay between the leading and ensuing trailing edge in the second delayed signal NEG_DEL is reduced relative to the time period between the corresponding rising and falling edge in the input signal IN by the time delay introduced by the second delay circuit portion 120.

When the time period between a falling edge and the ensuing rising edge of the input signal IN is less than or equal to the time delay introduced by the second delay circuit portion 120, no corresponding edges are included in the second delayed signal NEG_DEL. The second delay circuit portion 120 therefore effectively filters out negative pulses in the input signal IN with a duration less than or equal to the time delay introduced by the second delay circuit portion 120.

Typically, the time delays introduced by the first and second delay circuit portions 110, 120 are the same. However, this is not essential to the invention; the two delay circuit portions 110, 120 could equally introduce different time delays depending on the desired filtering characteristics of the circuit portion 100.

The logic circuit portion 130 functions as a Muller-C element. A Muller-C element typically has two output terminals, and in this embodiment the signal output terminal 104 is connected to just one of these. The truth table of the logic circuit portion 130 is shown in Table 1 below.

TABLE 1

| POS_DEL | NEG_DEL | OUT |
|---|---|---|
| 0 | 0 | 0 |
| 0 | 1 | No change |
| 1 | 0 | No change |
| 1 | 1 | 1 |

It will thus be seen that the logic circuit portion 130 outputs a signal OUT which retains its current state when the two delayed signals POS_DEL and NEG_DEL have different states, and which has a state that is dependent on the state of the two delayed signals POS_DEL and NEG_DEL when they have the same state. In this particular embodiment, the signal OUT output by the logic circuit portion 130 matches the states of the two delayed signals POS_DEL and NEG_DEL. It will be appreciated, however, that it could equally output a signal with the opposite state to the states of the two delayed signals POS_DEL and NEG_DEL when they have the same state, and thus have a truth table as shown in Table 2 below, without affecting the overall functionality of the circuit portion 100.

TABLE 2

| POS_DEL | NEG_DEL | OUT |
|---|---|---|
| 0 | 0 | 1 |
| 0 | 1 | No change |
| 1 | 0 | No change |
| 1 | 1 | 0 |

The operation of the circuit portion 100 shown in FIG. 1 will now be described in further detail with reference to FIGS. 2a, 2b, 3a and 3b. In these figures, for the sake of brevity, the two delay circuit portions 110, 120 are shown to output delayed signals POS_DEL, NEG_DEL having edges corresponding to the same type of edges in the input signal IN—i.e. rising edges corresponding to rising edges in the the input signal IN and falling edges corresponding to falling edges in the input signal IN. Similarly, the logic circuit portion 130 is shown to output a signal according to the truth table shown in Table 1—i.e. which matches the states of the two delayed signals POS_DEL, NEG_DEL. It will be appreciated that these figures are merely examples, and that the principles discussed here would equally apply if either or both of the delay circuit portions 110, 120 were to output delayed signals POS_DEL, NEG_DEL respectively having edges corresponding to the opposite type of edges in the input signal IN signals, and/or if the logic circuit portion 130 were to output a signal according to the truth table shown in Table 2.

It will also be appreciated that there may, in reality, be a marginal time delay introduced to rising edges in the input signal by the first delay circuit portion 110, and similarly introduced to falling edges in the input signal by the second delay circuit portion 120, due to unavoidable propagation delays of signals through electronic components and interconnects. For the sake of simplicity, these marginal time delays are not shown in the examples of FIGS. 2a, 2b, 3a and 3b.

FIG. 2a illustrates how the states of the signals IN, POS_DEL, NEG_DEL and OUT shown in FIG. 1 change in an example situation where the input signal IN includes a ‘long’ positive pulse between a rising edge 202 and an ensuing falling edge 204 which has a duration longer than the time delay introduced by the delay circuit portions 110, 120.

The rising edge 202 of the input signal IN is received at the same time by the first delay circuit portion 110 and the second delay circuit portion 120. The second delay circuit portion 120 does not introduce a deliberate time delay to the rising edge, 202 and thus the second delayed signal NEG_DEL includes a rising edge 212 occurring at substantially the same time as the rising edge 202 in the input signal IN. The first delay circuit portion 110, on the other hand, introduces a time delay to the rising edge 202, and thus the first delayed signal POS_DEL includes a rising edge 206 which occurs at a time delay relative to the rising edge 202.

The ensuing falling edge 204 of the input signal IN is also received at the same time by the first and second delay circuit portions 110, 120. The first delay circuit portion 110 does not introduce a deliberate time delay to the falling edge 204, and thus the first delayed signal POS_DEL includes a falling edge 208 occurring at substantially the same time as the falling edge 204. The second delay circuit portion 120, on the other hand, introduces a time delay to the falling edge 204, and thus the second delayed signal NEG_DEL includes a falling edge 214 which occurs at a delayed time relative to the falling edge 204.

It will thus be seen that the positive pulse in the first delayed signal POS_DEL is reduced in duration relative to the positive pulse in the input signal IN by the time delay introduced to the rising edge 202 by the first delay circuit portion 110. Similarly, the positive pulse in the second delayed signal NEG_DEL is increased in duration relative to the positive pulse in the input signal IN by the time delay introduced to the falling edge 204 by the second delay circuit portion 120.

The output signal OUT output by the logic circuit portion 130, in view of the truth table of Table 1, includes a rising edge 216 occurring at substantially the same time as the rising edge 206 in the first delayed signal POS_DEL, since that is the time at which both delayed signals POS_DEL, NEG_DEL become the same state (i.e. a logic ‘1’). Similarly, the output signal OUT includes a falling edge 218 occurring at substantially the same time as the falling edge 214 in the second delayed signal NEG_DEL, since that is the time at which both delayed signals POS_DEL, NEG_DEL become the same state (i.e. a logic ‘0’). In between these, the output signal OUT retains its state (logic ‘1’).

It will thus be seen that the positive pulse in the output signal OUT has the same duration as the positive pulse in the input signal IN, but occurring at a time delay relative to the input signal IN determined by the time delays introduced by the two delay circuit portions 110, 120.

FIG. 2b illustrates how the states of the signals IN, POS_DEL, NEG_DEL and OUT shown in FIG. 1 change in an example situation where the input signal IN includes a ‘long’ negative pulse between a rising edge 222 and an ensuing falling edge 224 which has a duration longer than the time delay introduced by the delay circuit portions 110, 120.

For similar reasons as those outlined above, the falling edge 226 in the first delayed signal POS_DEL occurs at substantially the same time as the falling edge 222 in the input signal. The falling edge 232 in the second delayed signal NEG_DEL, however, occurs at time delay relative to the falling edge 222.

Similarly, the rising edge 234 in the second delayed signal NEG_DEL occurs at substantially the same time as the rising edge 224 of the input signal. The rising edge 228 in the first delayed signal POS_DEL, however, occurs at a time delay relative to the rising edge 224.

It will thus be seen that the negative pulse in the second delayed signal NEG_DEL is reduced in duration relative to the negative pulse in the input signal IN by the time delay introduced to the falling edge 222 by the second delay circuit portion 120. Similarly, the negative pulse in the first delayed signal POS_DEL is increased in duration relative to the negative pulse in the input signal IN by the time delay introduced to the rising edge 224 by the first delay circuit portion 110.

For the same reasons as outlined above, the output signal OUT output by the logic circuit portion 130, includes a falling edge 236 occurring at substantially the same time as the falling edge 232 in the second delayed signal NEG_DEL. Similarly, the output signal OUT includes a rising edge 238 occurring at substantially the same time as the rising edge 228 in the first delayed signal POS_DEL.

Thus the negative pulse in the output signal OUT has the same duration as the negative pulse in the input signal IN, but occurring at a time delay relative to the input signal IN determined by the time delays introduced by the two delay circuit portions 110, 120.

FIG. 3a illustrates how the states of the signals IN, POS_DEL, NEG_DEL and OUT shown in FIG. 1 change in an example situation where the input signal IN includes a ‘short’ positive pulse between a rising edge 302 and an ensuing falling edge 304 which has a duration shorter than the time delays introduced by the delay circuit portions 110, 120.

For the same reasons as outlined above, the second delayed signal NEG_DEL includes a rising edge 306 occurring at substantially the same time as the rising edge 302. Similarly, the second delayed signal NEG_DEL includes a falling edge 308 occurring at a time delay relative to the falling edge 304.

However, the rising edge 302 is delayed by the first delay circuit portion 110 by an amount greater than the time period between the rising edge 302 and the falling edge 304 in the input signal. Thus, as mentioned previously, the first delayed signal POS_DEL does not contain any edges which correspond to the rising edge 302 nor falling edge 304 in the input signal—i.e. the first delay circuit portion 110 effectively filters out the ‘short’ positive pulse in the input signal IN.

The output signal OUT, output by the logic circuit portion 130, therefore also does not contain any edges which correspond to the rising edge 302 nor falling edge 304 in the input signal, in view of the truth table shown in Table 1, since there is no time at which both the first delayed signal POS_DEL and the second delayed signal NEG_DEL are both in a logic ‘1’ state. The ‘short’ positive pulse in the input signal IN is effectively removed by the circuit portion 100 in the output signal OUT.

FIG. 3b illustrates how the states of the signals IN, POS_DEL, NEG_DEL and OUT shown in FIG. 1 change in an example situation where the input signal IN includes a ‘short’ negative pulse between a falling edge 312 and an ensuing rising edge 314 which has a duration shorter than the time delays introduced by the delay circuit portions 110, 120.

For the same reasons as outlined above, the first delayed signal POS_DEL includes a falling edge 316 occurring at substantially the same time as the falling edge 312. Similarly, the first delayed signal POS_DEL includes a rising edge 318 occurring at a time delay relative to the rising edge 314.

However, the falling edge 312 is delayed by the second circuit portion 120 by an amount greater than the time period between the rising edge 312 and the falling edge 314 in the input signal. Thus, the second delayed signal NEG_DEL does not contain any edges which correspond to the falling edge 312 nor rising edge 314 in the input signal—i.e. the second delay circuit portion 120 effectively filters out the ‘short’ negative pulse in the input signal IN.

The output signal OUT, output by the logic circuit portion 130, therefore also does not contain any edges which correspond to the falling edge 312 nor rising edge 314 in the input signal, since there is no time at which both the first delayed signal POS_DEL and the second delayed signal NEG_DEL are both in a logic ‘0’ state. The ‘short’ negative pulse in the input signal IN is effectively removed by the circuit portion 100 in the output signal OUT.

It will thus be seen that the circuit portion 100 effectively acts as a glitch filter which removes ‘short’ positive and negative pulses which have durations less than or equal to the time delays introduced by the first and second delay circuit portions 110, 120.

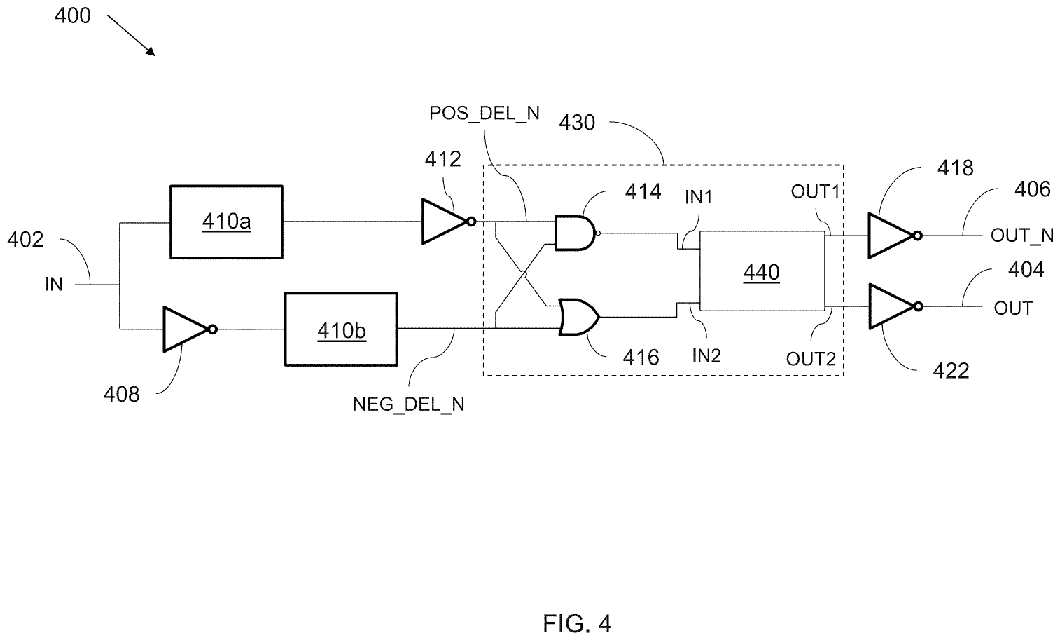

FIG. 4 shows a circuit portion 400 in accordance with a second embodiment of the invention which operates using similar principles to the circuit portion 100 shown in FIG. 1.

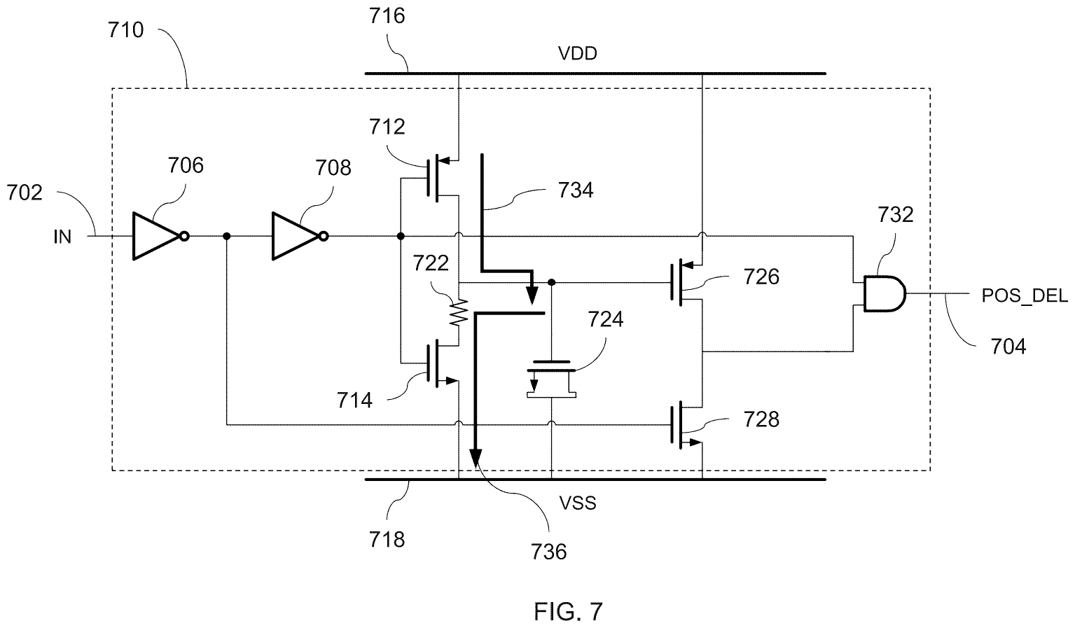

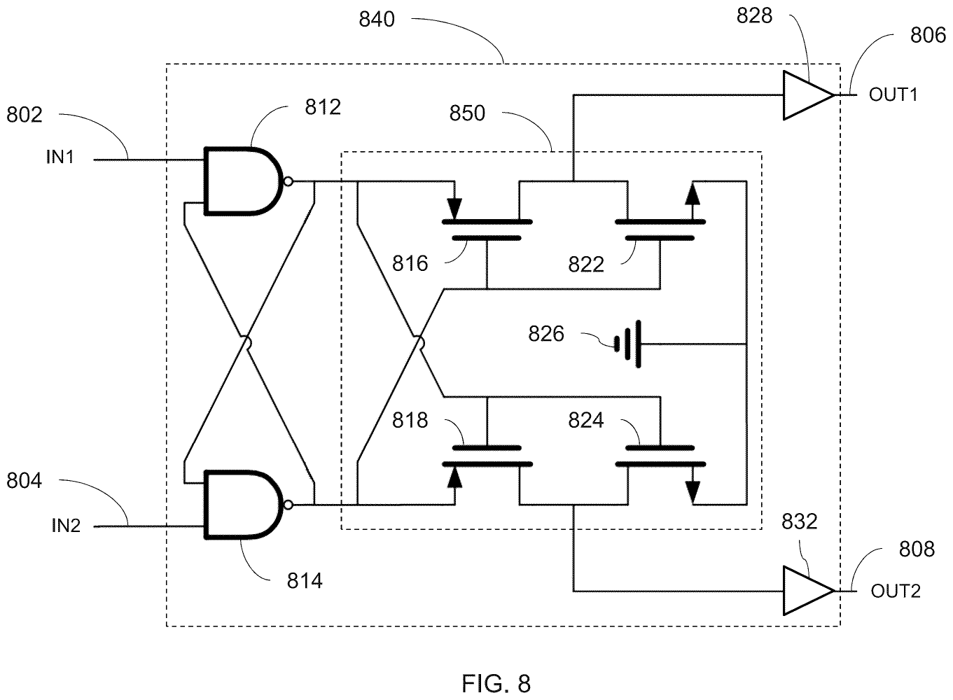

The circuit portion 400 comprises a signal input 402 for receiving the digital input signal IN, two signal outputs 404, 406 for outputting the overall digital output signal OUT and an inverted digital output signal OUT_N respectively. It further comprises a first rising edge delay circuit portion 410a, a second rising edge delay circuit portion 410b, four inverters 408, 412, 418, 422, and a logic circuit portion 430 comprising a NAND gate 414, an OR gate 416 and a mutex circuit portion 440. The first and second rising edge delay circuit portions 410a, 410b are identical to one another and are described in more detail later with reference to FIG. 7., The mutex circuit portion 440 is described in more detail later with reference to FIG. 8.

The input of the first rising edge delay circuit portion 410a is coupled to the overall signal input 402. The output of the first rising edge delay circuit portion 410a is coupled to the input terminal of one of the inverters 412. The first rising edge delay circuit portion 410a introduces a time delay to rising edges in the input signal IN in the same manner as the first delay circuit portion 110 described previously. The output of the inverter 412 is therefore an inverted version of the first delayed signal POS_DEL_N, which has the same timing characteristics as the first delayed signal POS_DEL described previously but with inverted edges.

The input terminal of another of the inverters 408 is coupled to the overall signal input 402, and the output terminal of the inverter 408 is coupled to the input of the second rising edge delay circuit portion 410b. Since the inverter 408 inverts the input signal IN before rising edges are delayed by the second rising edge delay circuit portion 410b, the second rising edge delay circuit portion 410b effectively introduces a time delay to falling edges in the input signal IN, as these are changed to rising edges by the inverter 408. The output of the second rising edge delay circuit portion 410b is therefore an inverted version of the second delay signal NEG_DEL_N, which has the same timing characteristics as the second delayed signal NEG_DEL described previously but with inverted edges.

The output terminal of the inverter 412 is coupled to one input terminal of one of the NAND gates 414 and one input terminal of the OR gate 416. The output of the second rising edge delay circuit portion 410b is coupled to the other input terminal of the NAND gate 414 and the other input terminal of the OR gate 416. The output terminal of the NAND gate 414 is coupled to the first input of the mutex circuit portion 440, and the output terminal of the OR gate 416 is coupled to the second input of the mutex circuit portion 440. The mutex circuit portion 440 has two outputs, OUT1 and OUT2 which via respective inverters 418, 422 provide the inverted digital output signal OUT_N and non-inverted digital output signal OUT respectively. Either of these overall outputs 404, 406 can be used, dependent on whether it is desired to generate a non-inverted or inverted output signal relative to the input signal IN.

The mutex circuit portion, which is described in greater detail later on, has a truth table according to that shown in Table 3 below.

TABLE 3

| IN1 | IN2 | OUT1 | OUT2 |
|---|---|---|---|
| 0 | 0 | 0 | 0 |
| 0 | 1 | 0 | 1 |
| 1 | 0 | 1 | 0 |
| 1 | 1 | No change | No change |

The mutex circuit portion 440 outputs the first signal OUT1 which retains its current state when both of the input signals IN1, IN2 are logic ‘1’s, and which matches the state of the first mutex input signal IN1 otherwise. Similarly, the mutex circuit portion 440 outputs the second signal OUT2 which retains its current state when both of the input signals IN1, IN2 are logic ‘1’s, and which matches the state of the second mutex input signal IN2 otherwise. The inclusion of the mutex circuit portion 440 helps reduce meta-stability in the outputs OUT and OUT_N of the circuit portion 400.

This configuration of the NAND gate 414, the OR gate 416 and the mutex circuit portion 440 causes the logic circuit portion 430 as a whole to output the signals OUT1 and OUT2 according to the truth table shown in Table 4 below. It will be appreciated therefore that the logic circuit portion 430 functions as a Muller-C element in the same manner as the logic circuit portion 110 shown in FIG. 1 (see tables 1 & 2) for the inverted delayed signals POS_DEL_N and NEG_DEL_N.

TABLE 4

| POS_DEL_N | NEG_DEL_N | OUT1 | OUT2 |
|---|---|---|---|
| 0 | 0 | 1 | 0 |
| 0 | 1 | No change | No change |
| 1 | 0 | No change | No change |
| 1 | 1 | 0 | 1 |

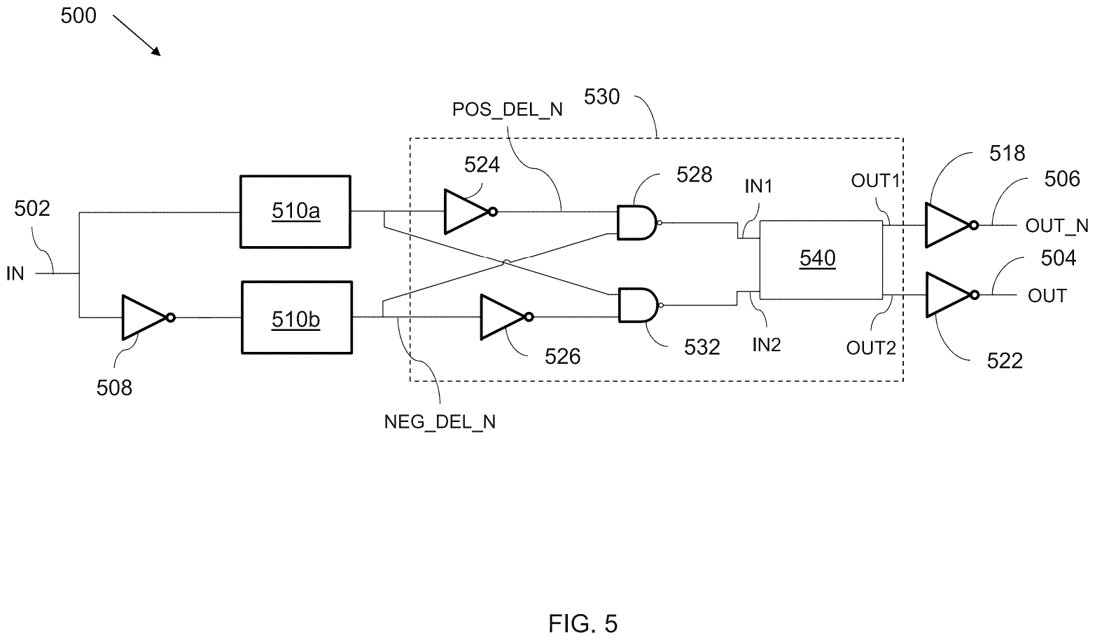

FIG. 5 shows a circuit portion 500 in accordance with a third embodiment of the invention which operates using similar principles to the circuit portion 100 shown in FIG. 1.

The circuit portion 500 has a similar structure to the circuit portion 400, with a signal input 502, two overall signal outputs 504, 506, a first rising edge delay circuit portion 510a, a second rising edge delay circuit portion 510b, and inverters 508, 518, 522 being connected in substantially the same manner and providing the same function as the equivalent parts of the circuit portion 400 as described previously (indicated with similar reference signs, e.g. 402 and 502).

The differences between the circuit portion 500 and the circuit portion 400 lie in the logic circuit portion 530, which comprises two inverters 524, 526, two NAND gates 528, 532, and a mutex circuit portion 540 which operates in the same manner as the mutex circuit portion 440 of the previous embodiment. The output of the first rising edge delay circuit portion 510a is coupled to the input terminal of the inverter 524 (in common with the previous embodiment), and to one input terminal of one of the NAND gates 532. The output of the second rising edge delay circuit portion 510b is coupled to the input terminal of the other inverter 526, and to one input terminal of the other NAND gate 528. The output terminal of the inverter 524 is coupled to the other input terminal of the NAND gate 528, and the output terminal of the inverter 526 is coupled to the other input terminal of the NAND gate 532. The output terminals of the NAND gates 528, 532 are coupled to the inputs of the mutex circuit portion 540.

This configuration of the inverters 524, 526, the NAND gates 528, 532, and the mutex circuit portion 540 causes the logic circuit portion 530 to output the signals OUT1 and OUT2 according to the truth table shown in Table 4 above. The logic circuit portion 540 therefore also functions as a Muller-C element for the inverted delayed signals POS_DEL_N and NEG_DEL_N in the same manner as the logic circuit portion 440 shown in FIG. 4.

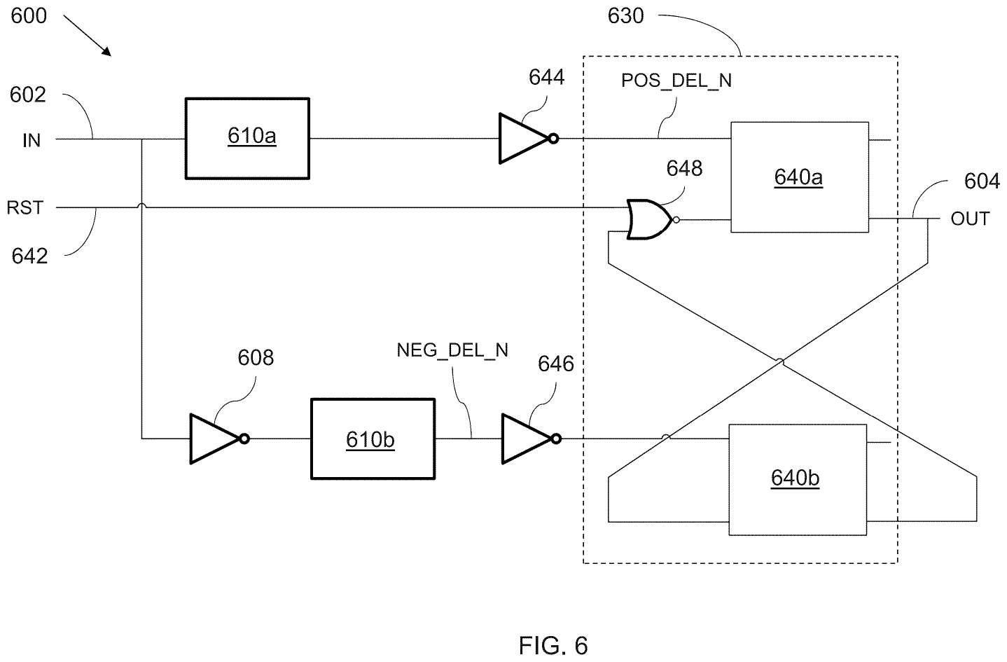

FIG. 6 shows a circuit portion 600 in accordance with a fourth embodiment of the invention which operates using similar principles to the circuit portion 100 shown in FIG. 1.

The circuit portion 600 comprises a signal input 602, an inverter 608, a first rising edge delay circuit portion 610a and a second rising edge delay circuit portion 610b connected in the same manner as the equivalent parts of the circuit portions 400 & 500 shown in FIGS. 4 & 5. The circuit portion 600 also comprises a reset signal input 642, two additional inverters 644, 646, a NOR gate 648 and two mutex circuit portions 640a, 640b.

The output of the first rising edge delay circuit portion 610a is coupled to the input terminal of the first inverter 644. The output terminal of that inverter 644 is connected to a first input of the first mutex circuit portion 640a. The output of the second rising edge delay circuit portion 610b is coupled to the input terminal of another inverter 646, and the output terminal of that inverter 646 is coupled to a first input terminal of the second mutex circuit portion 640b. The reset signal input 642 is coupled to one input terminal of the NOR gate 648, and the other input terminal of the NOR gate 648 is coupled to an output of the second mutex circuit portion 640b.

The output terminal of the NOR gate 648 is coupled to a second input terminal of the first mutex circuit portion 640a. The second input terminal of the second mutex circuit portion 640b is coupled to an output terminal of the first mutex circuit portion 640a. The output terminal of the first mutex circuit portion 640a also provides the overall signal output 604.

The two mutex circuit portions 640a, 640b can thus be seen to be cross-coupled, with the cross-coupling including the OR gate 648 to provide a reset function.

In use the reset signal input 642 receives a reset signal RST which essentially acts as an enable signal for the circuit portion 600 when it is in a logic ‘0’ state. The configuration of the NOR gate 648 and the two mutex circuit portions 640a, 640b cause the logic circuit portion 630 to output the signal OUT according to the truth table shown in Table 5 below. Thus, the logic circuit portion 630 also operates as a Muller-C element for the inverted delayed signals POS_DEL_N and NEG_DEL_N, in the same manner as the logic circuit portions 430 and 530 shown in FIGS. 4 & 5.

TABLE 5

| POS_DEL_N | NEG_DEL_N | OUT |
|---|---|---|
| 0 | 0 | 0 |
| 0 | 1 | No change |
| 1 | 0 | No change |
| 1 | 1 | 1 |

In particular, the two mutex circuit portions 640a, 640b operate in a loop in which they alternately wait for edges from the first and second rising edge delay circuit portions 610a, 610b respectively. The first mutex circuit portion 640a waits for a valid rising edge that validly propagates through the first rising edge delay circuit portion 610a, then the second mutex circuit portion 640b waits for a valid falling edge that validly propagates through the inverter 608 and the second rising edge delay circuit portion 610b, as described in more detail previously. This configuration ensures that any ‘short’ positive and negative pulses as described previously are handled safely by a mutex circuit portion in a ‘wait’ configuration. The addition of the reset signal terminal 642 for receiving the reset signal RST and the NOR gate 648 ensures that the cross-coupled mutex circuit portions 640a, 640b are initialised correctly when the circuit portion 600 is enabled.

In each of the embodiments of FIGS. 4, 5 and 6, the circuit structure for the pairs of delay circuit portions 410a, 410b; 510a, 510b; and 610a, 610b can be identical to each other. This advantageously helps alleviate process, voltage and temperature variations across different circuits by allowing the same components and arrangement to be used for delay of both rising and falling edges. This can help ensure that, if desired, the delay introduced by each of the delay circuit portions 410a, 410b; 510a, 510b; and 610a, 610b is substantially constant, thus ensuring uniform filtering for ‘short’ positive and negative pulses.

FIG. 7 shows a rising edge delay circuit portion 710 in more detail. The rising edge delay circuit portion 710 is one example of a circuit portion suitable for use as the rising edge delay circuit portions 410a, 410b; 510a, 510b; and 610a, 610b shown in FIGS. 4-6, and in the first and second circuit portions 110, 120 shown in FIG. 1.

An input 702 is provided by the input terminal of a first inverter 706. The output terminal of the first inverter 706 is coupled to the input terminal of a second inverter 708. The output terminal of the second inverter 708 is coupled to the gate terminals of a first PMOS transistor 712 and a first NMOS transistor 714. The source terminals of the first and a second PMOS transistors 712, 726 are coupled to the positive supply rail, and the source terminals of first and second NMOS transistors 714, 728 are coupled to the negative supply rail 718. The drain terminal of the first PMOS transistor 712 is coupled to one end of a resistor 722, to the gate terminal of a second PMOS transistor 726, and to one side of a capacitor 724. The other end of the resistor 722 is coupled to the drain terminal of the first NMOS transistor 714. The other side of the capacitor 724 is coupled to the negative supply rail 718.

One input terminal of an AND gate 732 is coupled to the output terminal of the second inverter 708, and the other input terminal of the AND gate 732 is coupled to the drain terminals of the second PMOS transistor 726 and the second NMOS transistor 728, which are also coupled to each other. The gate terminal of the second NMOS transistor 728 is coupled to the output terminal of the first inverter 706. The output terminal of the AND gate 732 is provides an output 704 of the rising edge delay circuit portion 710.

The capacitor 724 in this embodiment is implemented as an NMOS transistor having its source and drain terminals connected together. It will be appreciated that the capacitor 724 can be implemented in any suitable manner, however.

When a falling edge is received at the input 702, a first current path 734 is formed between the positive supply rail 716 and the capacitor 724 through the first PMOS transistor 712 which charges the capacitor 724. Since there is minimal resistance in this current path 734, the RC time constant is very small and thus the capacitor 724 charges very quickly. This causes the voltage at the gate terminal of the second PMOS transistor 726 to quickly rise to VDD, causing the voltage at the drain terminal of the second PMOS transistor 726 to quickly fall to VSS.

On the other hand, when a rising edge is received at the input terminal 702, a second current path 736 is formed between the negative supply rail 718 and the capacitor 724 through the first NMOS transistor 714 which discharges the capacitor 724. Since the resistor 722 forms part of the second current path 736, the RC time constant is greater and thus the capacitor 724 discharges more slowly. This causes the voltage at the gate terminal of the second PMOS to fall to VSS more slowly, causing the voltage at the drain terminal of the second PMOS transistor 726 to rise to VDD more slowly.

Thus it will be seen that rising edges arrive at the input terminal of the AND gate 732 from the drain terminals of the second PMOS transistor 726 after a greater time delay relative to the time they are received at the input terminal 702, than falling edges. Since the input signal IN is fed to the other input terminal of the AND gate 732 via the two inverters 706, 708—i.e. non-inverted and without significant delay—the AND gate will only output a logical ‘1’ when a positive pulse (i.e. a rising edge followed by a falling edge) in the input signal IN has a duration that is longer than the time delay introduced to rising edges by the RC circuit formed in the second current path 736. If a positive pulse in the input signal IN is shorter than this time delay, the rising edge will not reach the input of the AND gate 732 from the drain terminal of the second PMOS transistor 726 quickly enough, and no pulse will be output by the AND gate 732.

Positive pulses in the input signal IN which are greater than the time delay to rising edges introduced by the RC circuit output by the AND gate 704 are reduced in duration at the output of the AND gate 732 by the same time delay. Conversely, negative pulses (i.e. falling edges following by rising edges) in the input signal IN are increased in duration at the output of the AND gate 732 by the same time delay. The value of this time delay is primarily determined by the resistance of the resistor 722 and the capacitance of the capacitor 724.

Those skilled in the art will appreciate that the PMOS transistors 712, 726 and the NMOS transistors 714, 728 may be straightforwardly swapped for transistors of the opposite type, provided appropriate modifications are made to the other parts of the delay circuit portion 710 and how the transistors 712, 714, 726, 728 are connected thereto.

FIG. 8 shows a mutex circuit portion 840 in more detail. The mutex circuit portion 840 is one example of a circuit portion suitable for use as the mutex circuit portions 440; 540; and 640a, 640b shown in FIGS. 4-6.

The mutex circuit portion 840 comprises a first input 802, a second input 804, a first output 806, a second output 808, two NAND gates 812, 814, a first PMOS transistor 816, a second PMOS transistor 818, a first NMOS transistor 822, a second NMOS transistor 824, and a ground 826. The PMOS transistors 816, 818 and the NMOS transistors 822, 824 collectively form a meta-stability filter 850. In this example the mutex circuit portion further comprises two single-ended amplifiers 828, 832, but these are optional.

The first input 802 is coupled to an input terminal of the first NAND gate 812, and the second input 804 is coupled to an input terminal of the second NAND gate 814. The other input terminal of the first NAND gate 812 is coupled to the output terminal of the second NAND gate 814, and the other input terminal of the second NAND gate 814 is coupled to the output terminal of the first NAND gate 812. The output terminal of the first NAND gate 812 is also coupled to the source terminal of the first PMOS transistor 816, and to the gate terminals of the second PMOS transistor 818 and the second NMOS transistor 824.

The output terminal of the second NAND gate 814 is also coupled to the source terminal of the second PMOS transistor 818, and to the gate terminals of the first PMOS transistor 816 and the first NMOS transistor 822. The drain terminals of the first PMOS transistor 816 and the first NMOS transistor 822 are coupled to the first output 806, via the optional amplifier 828. The drain terminals of the second PMOS transistor 818 and the second NMOS transistor 824 are coupled to the second terminal 808, via the optional amplifier 832. The source terminals of the first NMOS transistor 822 and the second NMOS transistor 824 are coupled to ground 826.

This configuration causes the mutex circuit portion 840 to produce output signals OUT1, OUT2 according to the truth table shown in Table 3 above. In particular, the configuration of the two NAND gates 812, 814 provide this overall logical operation, while the meta-stability filter 850 prevents any meta-stability in the outputs OUT1, OUT2 cause by e.g. like edges arriving from the input signals IN1, IN2 at the same time.

Those skilled in the art will appreciate that the PMOS transistors 816, 818 and the NMOS transistors 822, 824 may be straightforwardly swapped for transistors of the opposite type, provided appropriate modifications are made to the other parts of the delay circuit portion 710 and how the transistors 816, 818, 822, 824 are connected thereto.

1. A circuit portion for filtering digital signals, the circuit portion comprising:
an overall signal input for receiving a digital input signal, and an overall signal output for outputting a digital output signal;
a first delay circuit portion coupled to the signal input and configured to output a first delayed digital signal comprising one or more leading edges each corresponding to a rising edge of the input signal, and one or more trailing edges each corresponding to a falling edge of the input signal, each of said leading edges in the first delayed digital signal being subject to a first time delay relative to the corresponding rising edge in the input signal such that a time period between each leading edge and the ensuing trailing edge is shorter than a time period between the corresponding rising edge and ensuing falling edge in the input signal, the first delay circuit portion being configured such that it does not output a corresponding leading and trailing edge in the first delayed signal when the time period between the rising edge and the ensuing falling edge in the input signal is less than or equal to the first time delay;
a second delay circuit portion coupled to the signal input and configured to output a second delayed digital signal comprising one or more leading edges each corresponding to a falling edge of the input signal, and one or more trailing edges each corresponding to a rising edge of the input signal, each of said leading edges in the second delayed digital signal being subject to a second time delay relative to the corresponding falling edge in the input signal such that a time period between each leading edge and the ensuing trailing edge is shorter than a time period between the corresponding falling edge and ensuing rising edge in the input signal, the second delay circuit portion being configured such that it does not output a corresponding leading and trailing edge in the second delayed signal when the time period between the falling edge and the ensuing rising edge in the input signal is less than or equal to the second time delay; and
a logic circuit portion comprising a first input coupled to the first delay circuit portion, and a second input coupled to the output of the second delay circuit portion, the logic circuit portion being configured to output, to the overall signal output, the digital output signal which retains a current state when the first and second delayed digital signals have different states, and a state that is dependent on a state of the first and second delayed signals when the first and second delayed digital signals have the same state.

2. The circuit portion as claimed in claim 1, wherein the first and second time delays are equal to each other.

3. The circuit portion as claimed in claim 1, wherein the output signal output by the logic circuit portion has a state which matches a state of the first and second delayed digital signals when the first and second delayed digital signals have the same state.

4. The circuit portion as claimed in claim 1, wherein the logic circuit portion comprises a Muller-C circuit portion.

5. The circuit portion as claimed in claim 1, wherein the first delay circuit portion and the second delay circuit portion have substantially the same arrangement, except for the second delay circuit portion comprising an inverter at an input thereof such that the second delay circuit receives an inverted version of the digital input signal.

6. The circuit portion as claimed in claim 1, wherein the first and/or second delay circuit portion comprises a capacitance element and an impedance element arranged such that:
upon receipt of a first type of edge of the digital input signal, a first current path is formed between the capacitance element and a first supply rail;
upon receipt of a second type of edge of the digital input signal, a second current path is formed between the capacitance element and a second supply rail; and
wherein:
the impedance element forms part of the second current path, and does not form part of the first current path.

7. The circuit portion as claimed in claim 1, wherein the first and/or second delay circuit portion comprises:
a first inverter having an input terminal coupled to the overall signal input;
a second inverter having an input terminal coupled to an output terminal of the first inverter;
a first transistor of a first type having a first terminal coupled to a positive supply rail and a gate terminal coupled to an output terminal of the second inverter;
a first transistor of a second type having a first terminal coupled to a negative supply rail and a gate terminal coupled to the output of the second inverter;
a second transistor of the first type having a first terminal coupled to the positive supply rail and a gate terminal coupled to a second terminal of the first transistor of the first type;
a second transistor of the second type having a first terminal coupled to the negative supply rail and a gate terminal coupled to the output terminal of the first inverter; and
an AND gate having a first input terminal coupled to the output terminal of the second inverter, and a second input terminal coupled to a second terminal of the second transistor of the first type and to a second terminal of the second transistor of the second type, the AND gate providing said first delayed digital signal;
wherein:
a first terminal of an impedance element is coupled to the second terminal of the first transistor of the first type, to the gate terminal of the second transistor of the first type, and to a first terminal of a capacitance element;
a second terminal of the impedance element is coupled to a second terminal of the first transistor of the second type; and
a second terminal of the capacitance element is connected to the negative supply rail.

8. The circuit portion as claimed in claim 6, wherein the impedance element comprises a resistor and the capacitance element comprises a transistor having its drain and source terminals connected together.

9. The circuit portion as claimed in claim 1, wherein the logic circuit portion comprises an inverter at its output.

10. The circuit portion as claimed in claim 1, wherein the logic circuit portion comprises a first mutex circuit portion having first and second inputs and being configured to output a first mutex signal which retains a current state when said first and second inputs are in the same, predetermined state, and which has a state that matches the state of the first input otherwise.

11. The circuit portion as claimed in claim 10, wherein the first mutex circuit portion is configured to output a second mutex signal which retains a current state when said first and second inputs are in the same, predetermined state, and which has a state that matches the state of the second input mutex signal in all other cases.

12. The circuit portion as claimed in claim 11, wherein the first or second mutex signal provides the output digital signal.

13. The circuit portion as claimed in claim 10, wherein the first mutex circuit portion comprises:
a first and a second NAND gate each having two input terminals and an output terminal;
a first and a second transistor of a first type, each transistor comprising a gate terminal, a first terminal and a second terminal; and
a first and a second transistor of a second type, each transistor comprising a gate terminal, a first terminal and a second terminal;
wherein:
a first input terminal of the first NAND gate provides the first input of the first mutex circuit portion, a second input terminal of the first NAND gate is coupled to the output terminal of the second NAND gate, and the output terminal of the first NAND gate is coupled to the first terminal of the first transistor of the first type;
a first input terminal of the second NAND gate is coupled to the output terminal of the first NAND gate, a second input terminal of the second NAND gate is coupled to the second input of the first mutex circuit portion, and the output terminal of the second NAND gate is coupled to the first terminal of the second transistor of the first type;
the second terminal of the first transistor of the first type is coupled to the second terminal of the first transistor of the second type, and to the first output terminal of the first mutex circuit portion;
the first terminal of the first transistor of the second type is coupled to ground;
the second terminal of the second transistor of the first type is coupled to the second terminal of the second transistor of the second type, and to the second output of the first mutex circuit portion;
the first terminal of the second transistor of the second type is coupled to ground; and
the gate terminals of the first transistor of the first type and the first transistor of the second type are coupled to the output terminal of the second NAND gate; and
the gate terminals of the second transistor of the first type and the second transistor of the second type are coupled to the output terminal of the first NAND gate.

14. The circuit portion as claimed in claim 13, wherein the logic circuit portion comprises a single-ended amplifier coupled between the first or second output of the first mutex circuit portion and the output of the logic circuit portion.

15. The circuit portion as claimed in claim 10, wherein the logic circuit portion comprises:
a NAND gate having a first input terminal coupled to the output of the first delay circuit portion, a second input terminal connected to the output of the second delay circuit portion, and an output terminal coupled to the first input of the first mutex circuit portion; and
an OR gate having a first input terminal coupled to the output of the first delay circuit portion, a second input terminal coupled to an output of the second delay circuit portion, and an output terminal coupled to the second input of the first mutex circuit portion.

16. The circuit portion as claimed in claim 15, further comprising an inverter connected between the output of the first delay circuit portion and the first input terminals of the NAND gate and the OR gate.

17. The circuit portion as claimed in claim 10, wherein the logic circuit portion comprises:
a first inverter having an input terminal coupled to an output of the first delay circuit portion;
a second inverter having an input terminal coupled to an output of the second delay circuit portion;
a first NAND gate having a first input terminal coupled to an output terminal of the first inverter, a second input terminal coupled to the output of the second delay circuit portion, and an output terminal coupled to the first input of the first mutex circuit portion; and
a second NAND gate having a first input terminal coupled to the output of the first delay circuit portion, a second input terminal coupled to an output terminal of the second inverter, and an output terminal coupled to the second input of the first mutex circuit portion.

18. The circuit portion as claimed in claim 10, wherein the logic circuit portion further comprises a second mutex circuit portion having the same arrangement as the first mutex circuit portion, wherein the two mutex circuit portions are cross-coupled.

19. The circuit portion as claimed in claim 18, wherein the logic circuit portion comprises a NOR gate in the cross-coupling to provide a reset input.

20. The circuit portion as claimed in claim 18, further comprising:
a first inverter connected between the output of the first delay circuit portion and the first input of the first mutex circuit portion; and
a second inverter connected between the output of the second delay circuit portion and the first input of the second mutex circuit portion.
